(19) United States
(12) Patent Application Publication
(10) Pub. No.: US 2024/0056033 A1
(43) Pub. Date: Feb. 15, 2024

(54) SYSTEMS, DEVICES, AND METHODS RELATED TO POWER AMPLIFIER EMPLOYING CASCODE STAGE OUTPUT SWITCHING TO ELIMINATE BAND SELECT SWITCH

(71) Applicant: SKYWORKS SOLUTIONS, INC., Irvine, CA (US)

(72) Inventor: David Richard PEHLKE, Westlake Village, CA (US)

(21) Appl. No.: 18/233,379

(22) Filed: Aug. 14, 2023

Related U.S. Application Data
(60) Provisional application No. 63/371,446, filed on Aug. 15, 2022.

(51) Int. Cl. H03F 1/22; H03F 3/24

(52) U.S. Cl. CPC H03F 1/22; H03F 3/245; H03F 2200/451

(57) ABSTRACT

A power amplification system may include a shared common cascode input stage. A power amplification system may include a plurality of cascode output stages parallelly connected to the shared common cascode input stage, each cascode output stage associated with a frequency band.

### CROSS-REFERENCE TO RELATED APPLICATION(S)

This application claims priority to U.S. Provisional Application No. 63/371,446 filed Aug. 15, 2022, entitled “POWER AMPLIFIER EMPLOYING CASCODE STAGE OUTPUT SWITCHING TO ELIMINATE BAND SELECT SWITCH,” the disclosure of which is hereby expressly incorporated by reference herein in its respective entirety.

### BACKGROUND

### Field

The present disclosure generally relates to power amplifiers for radio-frequency (RF) applications.

### Description of the Related Art

In RF applications, an RF signal to be transmitted is typically generated by a transceiver. Such an RF signal can then be amplified by a power amplifier (PA), and the amplified RF signal can be routed to an antenna for transmission. Modern communication front-ends often employ broadband power amplifiers that are followed by one or more band select switches. The band select switches are employed to direct transmit signal to different filter RF paths for signal conditioning and emissions/intermodulation/Rx DeSense management.

### SUMMARY

In accordance with a number of implementations, the present disclosure relates to a power amplification system including: a cascode power amplifier (PA) configured to receive and amplify a radio-frequency (RF) signal, the cascode PA including: a shared common cascode input stage; and a plurality of cascode output stages parallelly connected to the shared common cascode input stage, each cascode output stage associated with a frequency band.

In some aspects, the techniques described herein relate to a power amplification system wherein the plurality of cascode output stages include a first cascode output stage and a second cascode output stage, the first cascode output stage associated with a first frequency band and a second cascode output stage associated with a second frequency band.

In some aspects, the techniques described herein relate to a power amplification system wherein the first cascode output stage receives an amount of voltage that activates the first cascode output stage to provide a first amplification path for the RF signal while the second cascode output stage does not receive the amount of voltage and does not provide a second amplification path.

In some aspects, the techniques described herein relate to a power amplification system wherein the first cascode output stage stops receiving the amount of voltage and stops providing the first amplification path for the RF signal while the second cascode output stage receives the amount of voltage to provide the second amplification path for the RF signal.

In some aspects, the techniques described herein relate to a power amplification system wherein provision of the first amplification path and the second amplification path alternates in a non-overlapping manner.

In some aspects, the techniques described herein relate to a power amplification system wherein the cascode input stage includes a first bipolar junction transistor (BJT), the first cascode output stage includes a second BJT, the second cascode output stage includes a third BJT, and a voltage greater than a forward-biasing voltage is applied to the second BJT while not applied to the third BJT.

In some aspects, the techniques described herein relate to a power amplification system wherein the cascode input stage includes a BJT, the first cascode output stage includes a first field-effect-transistor (FET), the second cascode output stage includes a second FET, and a voltage greater than a threshold voltage is applied to the first FET while not applied to the second FET.

In some aspects, the techniques described herein relate to a power amplification system further including a voltage supply system configured to provide a voltage greater than or equal to 11V to the plurality of cascode output stages, wherein the voltage supply system includes a boost DC/DC converter configured to generate the voltage based on a battery voltage.

In some aspects, the techniques described herein relate to a power amplification system wherein the voltage is provided to collectors of the plurality of cascode output stages.

In some aspects, the techniques described herein relate to a power amplification system wherein the plurality of cascode output stages have impedances of approximately 50 Ohms.

In some aspects, the techniques described herein relate to a power amplification system further including a transmit (Tx) filter coupled to the first cascode output stage and configured to condition a signal output by the first cascode output stage, the Tx filter configured to operate in the first frequency band.

In some aspects, the techniques described herein relate to a power amplification system wherein the Tx filter is coupled to the first cascode output stage by an amplification path that is free of an impedance transformation circuit.

In some aspects, the techniques described herein relate to a power amplification system wherein the Tx filter is coupled to the first cascode output stage by an amplification path that is free of a band select switch.

In some aspects, the techniques described herein relate to a wireless device including: a transceiver configured to generate a radio-frequency (RF) signal; a front-end module (FEM) in communication with the transceiver, the FEM including a packaging substrate configured to receive a plurality of components, the FEM further including a power amplification system implemented on the packaging substrate, the power amplification system including a cascode power amplifier (PA), the cascode PA including a shared common cascode input stage and a shared common cascode input stage and a plurality of cascode output stages parallelly connected to the shared common cascode input stage, each cascode output stage associated with a frequency band, the cascode PA configured to receive and amplify a radio-frequency (RF) signal; and an antenna in communication with the FEM, the antenna configured to transmit the amplified RF signal.

In some aspects, the techniques described herein relate to a wireless device wherein the plurality of cascode output stages include a first cascode output stage and a second cascode output stage, the first cascode output stage associated with a first frequency band and a second cascode output stage associated with a second frequency band.

In some aspects, the techniques described herein relate to a power amplification system wherein the first cascode output stage receives an amount of voltage that activates the first cascode output stage to provide a first amplification path for the RF signal while the second cascode output stage does not receive the amount of voltage and does not provide the second amplification path.

In some aspects, the techniques described herein relate to a power amplification system wherein the first cascode output stage stops receiving the amount of voltage and stops providing the first amplification path for the RF signal while the second cascode output stage receives the amount of voltage to provide a second amplification path for the RF signal.

In some aspects, the techniques described herein relate to a power amplification system wherein provision of the first amplification path and the second amplification path alternates in a non-overlapping manner.

In some aspects, the techniques described herein relate to a power amplification system wherein the first amplification path is free of a band select switch.

In some aspects, the techniques described herein relate to a method for processing a radio-frequency (RF) signal, the method including: providing a cascode power amplifier (PA) including a shared cascode input stage and a first cascode output stage and a second cascode output stage parallelly connected to the shared cascode input stage, the first cascode output stage associated with a first frequency band and the second cascode output stage associated with a second frequency band; applying an amount of voltage that activates the first cascode output stage to provide a first amplification path while not applying the amount of voltage to the second output stage to block a second amplification path; amplifying the RF signal with the cascode PA with the shared cascode input stage and the first cascode output stage through the first amplification path; routing the amplified RF signal to a downstream filter associated with the first frequency band.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a wireless system or architecture having an amplification system.

FIG. 2 shows that the amplification system of FIG. 1 can include a radio-frequency (RF) amplifier assembly having one or more power amplifiers (PAs).

FIGS. 3A-3E show non-limiting examples of how such a PA configurations.

FIGS. 4A-4C show an example power amplifier employing multiple cascode amplifiers that share a common cascode input stage, in accordance with one or more embodiments.

FIG. 5 illustrates an example selective application of forward-biasing voltages, in accordance with one or more embodiments.

FIG. 6 shows a conventional band select switch power amplification system 110 (FIG. 6).

FIG. 7 shows an improved parallel cascode output stages power amplification system, in accordance with one or more embodiments.

FIG. 8 show potential elimination of circuit components in view of FIGS. 6 and 7.

FIG. 9 shows some or all of a parallel cascode output stages power amplification system implemented in an example module.

FIG. 10 depicts an example wireless device.

### DETAILED DESCRIPTION OF SOME EMBODIMENTS

The present disclosure generally relates to power amplifiers for radio-frequency (RF) applications. In RF applications, an RF signal to be transmitted is typically generated by a transceiver. Such an RF signal can then be amplified by a power amplifier (PA), and the amplified RF signal can be routed to an antenna for transmission.

More specifically, the present disclosure relates to an improved circuit architecture that employs cascode state output switching in order to eliminate a need for a band select switch in an RF front-end (FE) architecture. Modern communication front-ends often employ broadband power amplifiers that are followed by one or more band select switches. The band select switches are employed to direct transmit signal to different filter RF paths for signal conditioning and emissions/intermodulation/Rx DeSense management. Typically, a band select switch, and functions thereof, are provided on a high performance separate silicon on insulator (SOI) die that desirably meets (i) extremely high power handling capability, (ii) minimum insertion loss, and (iii) linearity and harmonic generation requirements. However, satisfying all of the above requirements can be challenging. For instance, a band select switch provided on an SOI die can introduce penalties of additional in-line insertion loss of approximately 0.5 dB-1.0 dB, depending on frequency, and pose challenges arising from harmonic generation and intermodulation linearity requirements.

An improved approach disclosed herein proposes a solution that can eliminate the band select switch while maintaining routing of signals to different RF paths. The proposed solution can use at least one cascode amplifier configured with a shared cascode driver (input) stage and parallelly connected cascode gain (output) stages. Each of the cascode output stages can amplify signals having a particular frequency band and provide a separate amplification path (e.g., a separate signal path). With selective application of voltages to the cascode output stages, a selected amplification path from the separate amplification paths can be activated. For example, selective application of forward-biasing voltages to bases (for bipolar junction transistors (BJTs)) or greater-than-threshold voltages to gates (for field-effect transistors (FETs)) at the cascode gain stages can activate the selected amplification path. In contrast, simultaneously or optionally, selective non-application of such voltages can deactivate a non-selected amplification path. The activation and deactivation of one or more amplification paths can enable the proposed solution to provide a desired amplification path in a power amplifier assembly and provide an amplified output signal out of the power amplifier assembly. Accordingly, the proposed solution can do away with parallelly providing multiple amplified signals to a band select switch to be selected and, thus, eliminate the need for the band select switch. The proposed solution can simplify circuits, eliminate component count, and/or reduce circuit cost/size while providing lower insertion loss.

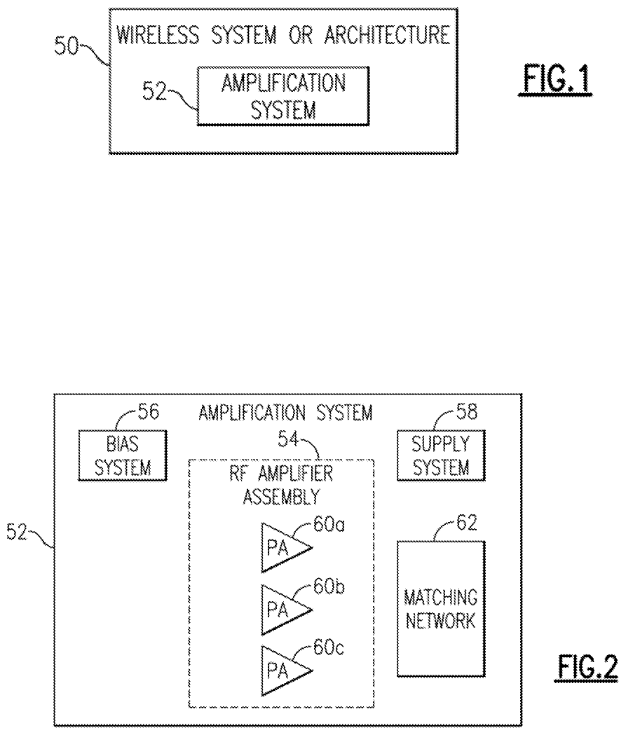

FIG. 1 depicts a wireless system or architecture 50 having an amplification system 52. In some embodiments, the amplification system 52 can be implemented as one or more devices, and such device(s) can be utilized in the wireless system/architecture 50. In some embodiments, the wireless system/architecture 50 can be implemented in, for example, a portable wireless device. Examples of such a wireless device are described herein.

FIG. 2 shows that the amplification system 52 of FIG. 1 can include a radio-frequency (RF) amplifier assembly 54 having one or more power amplifiers (PAs). In the example of FIG. 2, three PAs 60a-60c are depicted as forming the RF amplifier assembly 54. It will be understood that other numbers of PA(s) can also be implemented. It will also be understood that one or more features of the present disclosure can also be implemented in RF amplifier assemblies having other types of RF amplifiers.

In some embodiments, the RF amplifier assembly 54 can be implemented on one or more semiconductor dies, and such die can be included in a packaged module such as a power amplifier module (PAM) or a front-end module (FEM). Such a packaged module is typically configured to be mounted on a circuit board associated with, for example, a portable wireless device.

The PAs (e.g., 60a-60c) in the amplification system 52 can be typically biased by a bias system 56. Further, supply voltages (e.g., V_{CC}) for the PAs can be typically provided by a supply system 58. In some embodiments, either or both of the bias system 56 and the supply system 58 can be included in the foregoing packaged module having the RF amplifier assembly 54.

In some embodiments, the amplification system 52 can include a matching network 62. Such a matching network can be configured to provide input matching and/or output matching functionalities for the RF amplifier assembly 54.

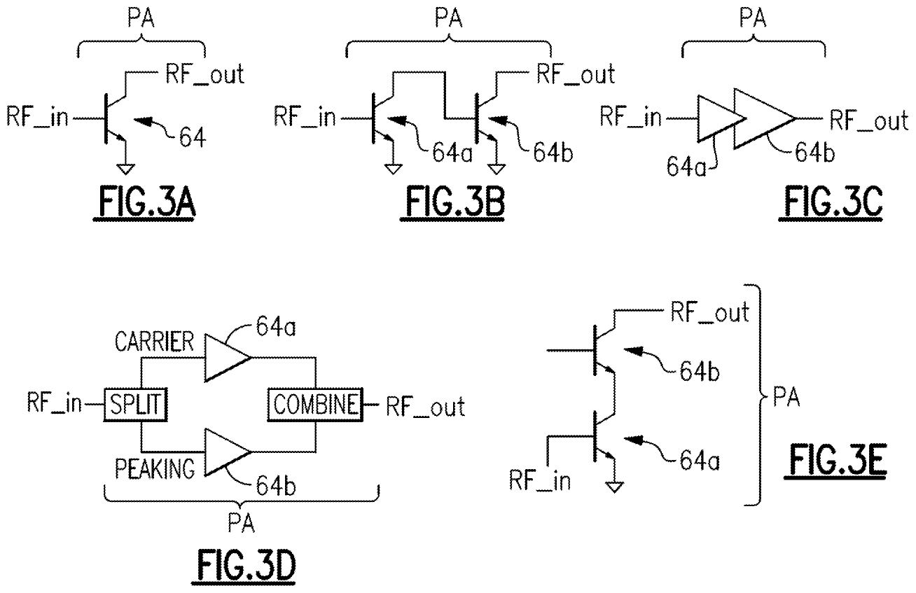

For the purpose of description, it will be understood that each PA (60) of FIG. 2 can be implemented in a number of ways. FIGS. 3A-3E show non-limiting examples of how such a PA can be configured. FIG. 3A shows an example PA having an amplifying transistor 64, where an input RF signal (RF_in) is provided to a base of the transistor 64, and an amplified RF signal (RF_out) is output through a collector of the transistor 64.

FIG. 3B shows an example PA having a plurality of amplifying transistors (e.g., 64a, 64b) arranged in stages. An input RF signal (RF_in) is shown to be provided to a base of the first transistor 64a, and an amplified RF signal from the first transistor 64a is shown to be output through its collector. The amplified RF signal from the first transistor 64a is shown to be provided to a base of the second transistor 64b, and an amplified RF signal from the second transistor 64b is shown to be output through its collector to thereby yield an output RF signal (RF_out) of the PA.

In some embodiments, the foregoing example PA configuration of FIG. 3B can be depicted as two or more stages as shown in FIG. 3C. The first stage 64a can be configured as, for example, a driver stage; and the second stage 64b can be configured as, for example, an output (gain) stage.

FIG. 3D shows that in some embodiments, a PA can be configured as a Doherty PA. Such a Doherty PA can include amplifying transistors 64a, 64b configured to provide carrier amplification and peaking amplification, respectively, of an input RF signal (RF_in), to yield an amplified output RF signal (RF_out). The input RF signal can be split into the carrier portion and the peaking portion by a splitter. The amplified carrier and peaking signals can be combined to yield the output RF signal by a combiner.

FIG. 3E shows that in some embodiments, a PA can be implemented in a cascode configuration having a cascode input (driver) stage and a cascode output (gain) stage. An input RF signal (RF_in) can be provided to a base of the first amplifying transistor 64a operated as a common emitter device (e.g., a cascode input stage). The output of the first amplifying transistor 64a can be provided through its collector and be provided to an emitter of the second amplifying transistor 64b operated as a common base device (e.g., a cascode output stage). The output of the second amplifying transistor 64b can be provided through its collector so as to yield an amplified output RF signal (RF_out) of the PA.

In the various examples of FIGS. 3A-3E, the amplifying transistors are described as bipolar junction transistors (BJTs) such as heterojunction bipolar transistors (HBTs). It will be understood that one or more features of the present disclosure can also be implemented in or with other types of transistors such as field-effect transistors (FETs).

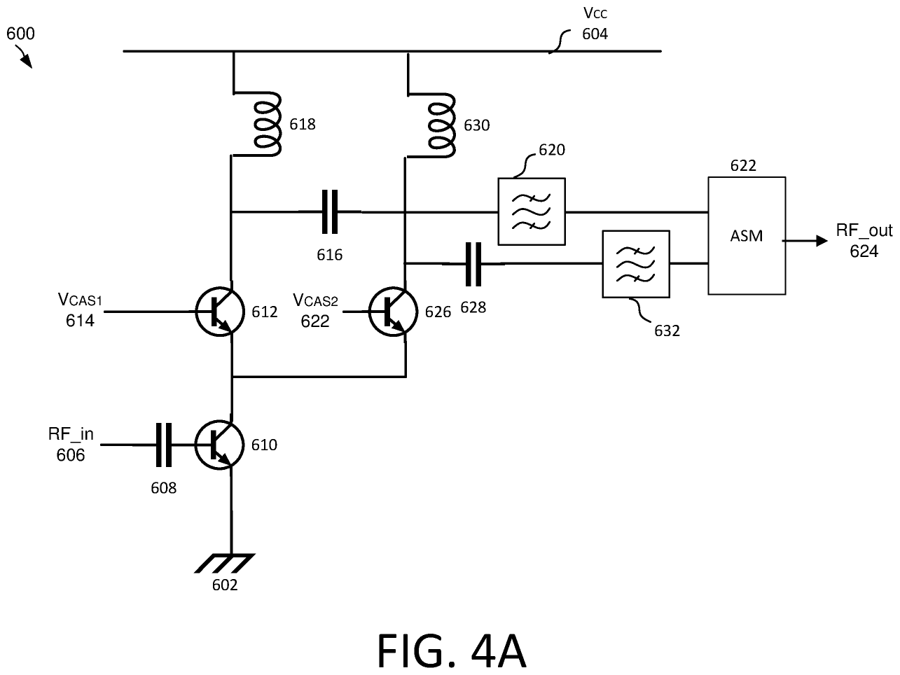

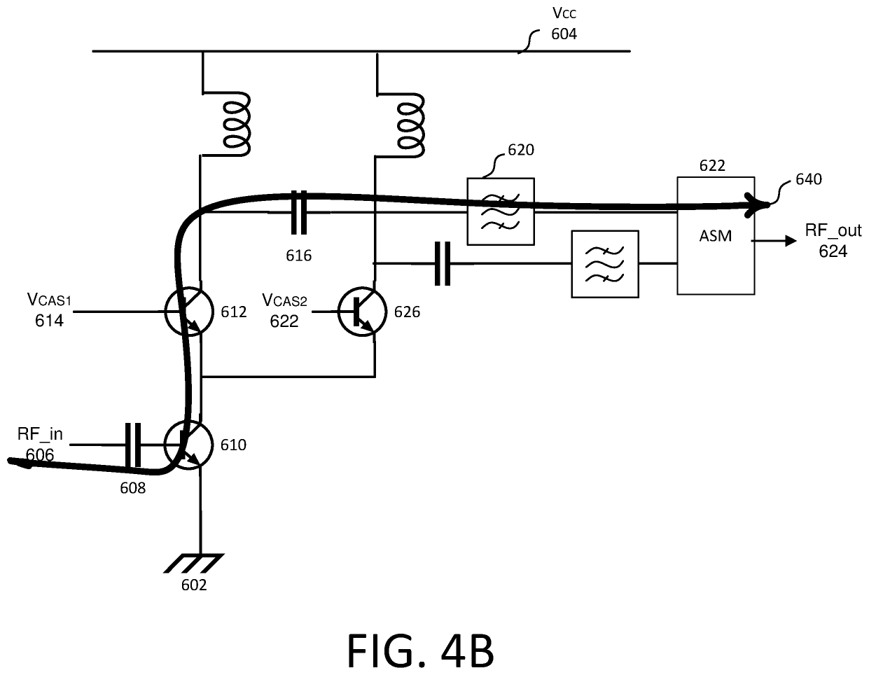

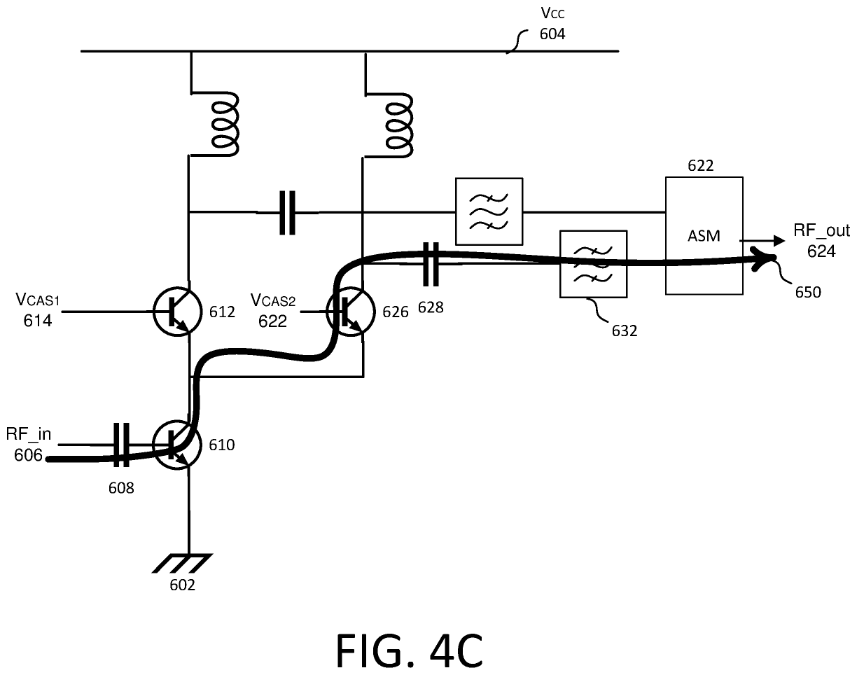

FIG. 4A shows an example power amplifier 600 employing multiple cascode amplifiers that share a common cascode input stage, in accordance with one or more embodiments. Two or more cascode gain (e.g., output) stages can be parallelly connected to the common cascode input stage. Pairings between the shared common cascode input stage and one of the parallelly connected cascode gain stages can be a PA implemented in the cascode configuration of FIG. 3E. While the example power amplifier 600 is illustrated with BJTs, it will be understood that the example power amplifier 600 can also be implemented with other types of transistors such as FETs. It will be further understood that any component and/or collection of components can be interchanged with functional equivalents. For example, a BJT may be replaced with a FET and functionally corresponding terms for the FET (e.g., gate, drain, source) can replace terms for the BJT (e.g., base, collector, emitter).

The shared common cascode input stage can include a first BJT 610 with its emitter connected to a ground 602 (or a ground-equivalent, such as a chassis). At its base, the first BJT 610 can be connected to an RF input signal source (RF_in) 606 through a DC-block capacitance 608. A collector of the first BJT 610 is shown to be parallelly connected to emitters of multiple BJTs configured as cascode output stages, such as a second BJT 612 and a third BJT 626.

A collector of the second BJT 612 is shown to be provided with a supply voltage 604 V_{CC} through a first choke inductance 618 and a collector of the second BJT 612 is shown to provide a first amplified signal. The first amplified signal from the second BJT 612 in a cascode output stage is shown to be routed through a first downstream capacitance 616. Optionally, a first filter 620 is shown to filter the first amplified signal and provide the filtered signal to an antenna switch module 622. Similarly, a collector of the third BJT 626 is shown to be provided with the supply voltage 604 Vcc through a second choke inductance 630 and a collector of the third BJT 626 is shown to provide a second amplified signal. The second amplified signal from the third BJT 626 in a cascode output stage is shown to be routed through a second downstream capacitance 628. Optionally, a second filter 632 is shown to filter the second amplified signal and provide the filtered signal to the antenna switch module 622 where selection of one or more antennae is desired. An RF output signal (RF_out) 624 can be provided to an antenna for transmission.

Each pairing between the first BJT 610 and one of the second BJT 612 or the third BJT 626 can complete a separate amplification path with selective application, and lack of application, of voltages V_{CAS1} 614 or V_{CAS2} 622 to the first BJT 612 or the second BJT 626, respectively. FIG. 4B illustrates a first amplification path 640. Similarly, FIG. 4C illustrates a second amplification path 650.

In FIG. 4B, V_{CAS1} 614 is a forward-biasing voltage that provides a conductive carrier channel between the emitter and the collector of the second BJT 612. In contrast, V_{CAS2} 622 is configured as a backward-biasing voltage (or a voltage that is below an activation threshold for the third BJT 626, e.g., less than 0.7V) that stops formation of a conductive carrier channel between the emitter and the collector of the third BJT 626. Such selective provision of V_{CAS1} 614 and V_{CAS2} 622 can provide the first amplification path 640 by enabling the RF_in 606 to transmit through the DC-block capacitance 608, the first BJT 610, the second BJT 612, the first downstream capacitance 616, the first filter 620, and the antenna switching module 622, thereby providing RF_out 624.

In FIG. 4C, V_{CAS2} 622 is a forward-biasing voltage that provides a conductive carrier channel between the emitter and the collector of the third BJT 626. In contrast, V_{CAS1} 614 is configured as a backward-biasing voltage (or a voltage that is below an activation threshold for the second BJT 612, e.g., less than 0.7V) that stops formation of a conductive carrier channel between the emitter and the collector of the second BJT 612. Such selective provision of V_{CAS1} 614 and V_{CAS2} 622 can provide the second amplification path 650 by enabling the RF_in 606 to transmit through the DC-block capacitance 608, the first BJT 610, the third BJT 626, the second downstream capacitance 628, the second filter 632, and the antenna switching module 622, thereby providing RF_out 624.

As shown in FIGS. 4B-4C, the two amplification paths 640, 650 are separately providable based on selective application of forward-biasing voltages to the second BJT 612 and the third BJT 626 with V_{CAS1} 614 and V_{CAS2} 622, respectively. If the power amplifier 600 of FIG. 4A is configured to route a first frequency band RF_in 606 to the first amplification path 640 and a second frequency band RF_in 606 to the second amplification path 650 with use of selective application of forward-biasing voltages, then the power amplifier 600 can select separate amplification and downstream components without reliance on a band select switch. Accordingly, the power amplifier 600 is capable of providing functionalities of a band select switch.

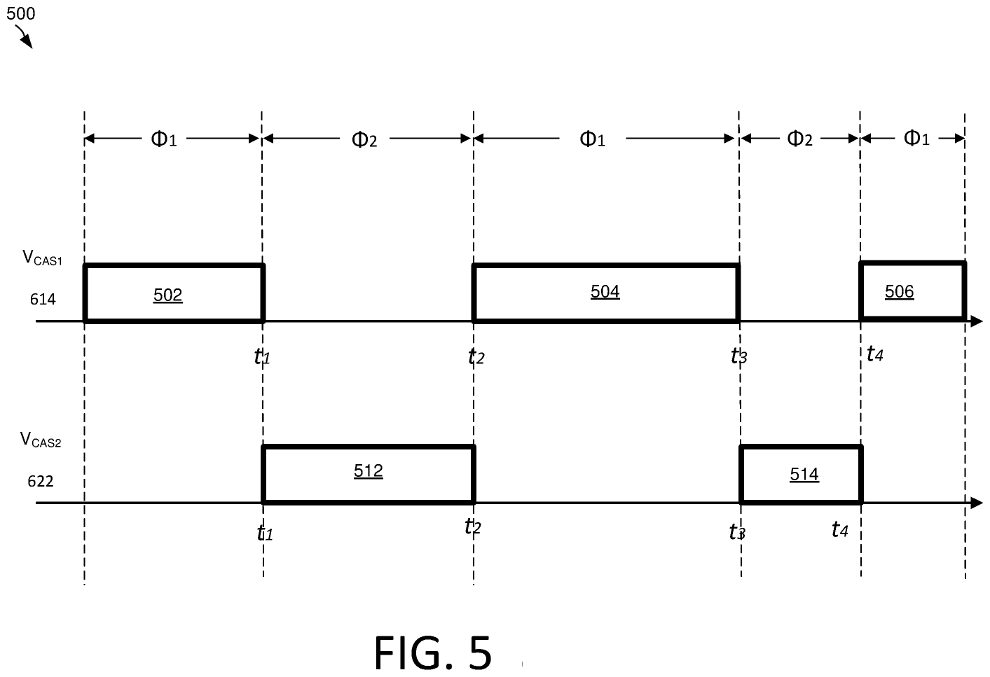

FIG. 5 illustrates an example selective application 500 of forward-biasing voltages to V_{CAS1} 614 and V_{CAS2} 622, in accordance with one or more embodiments. More specifically, the selective application 500 alternates application of forward-biasing voltages to V_{CAS1} 614 and V_{CAS2} 622 in two phases. In a first phase (Φ₁) reflective of FIG. 4B, forward-biasing voltage can be applied to V_{CAS1} 614 but not V_{CAS2} 622. In a second phase (Φ₂) reflective of FIG. 4C, forward-biasing voltage can be applied to V_{CAS2} 622 but not V_{CAS1} 614. Timing blocks 502, 504, 506 reflect time durations during which the power amplifier 600 of FIG. 4A is in the first phase of FIG. 4B. Timing blocks 512, 514 are reflect time durations during which the power amplifier 600 of FIG. 4A is in the second phase of FIG. 4C.

While FIGS. 4A-4C and FIG. 5 illustrate two cascode output stages associated with two separate amplification paths 640, 650, it will be understood that any number of cascode output stages can be parallelly provided with corresponding non-overlapping forward-biasing voltage phases. Accordingly, any number of amplification paths can be provided, including three, four, or any greater number.

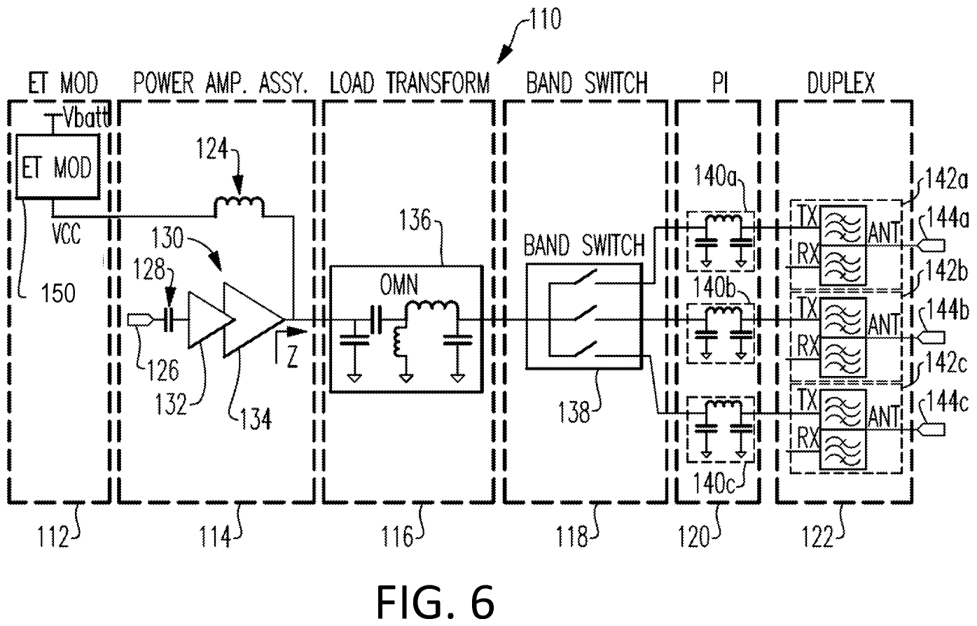

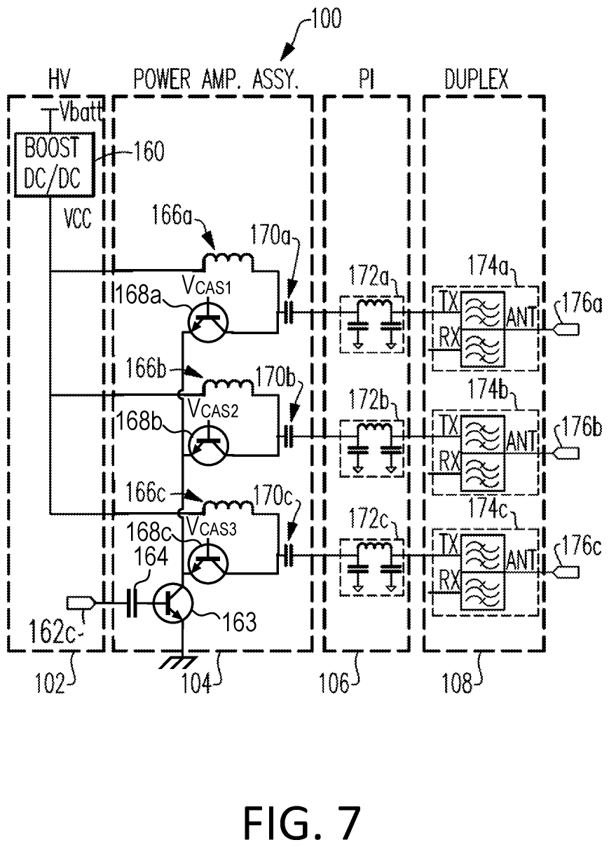

FIGS. 6 and 7 show a comparison between a conventional band select switch power amplification system 110 (FIG. 6) and an improved parallel cascode output stages power amplification system 100 (FIG. 7) to demonstrate elimination of a band select switch and improved RF transmission properties in the parallel cascode output stages power amplification system 100. For the purpose of comparison, it will be assumed that each power amplification system is configured to provide amplification for three frequency bands. However, it will be understood that more or fewer numbers of frequency bands can be utilized.

In the example of FIG. 6, the band select switch power amplification system 110 is shown to include a power amplifier assembly 114 having a broadband amplification path 130 capable of providing amplification for three frequency bands. The amplification path 130 can receive an input RF signal through a common input node 126, and such an RF signal can be routed to one or more amplification stages through, for example, a DC-block capacitance 128. The amplification stages can include, for example, a driver stage 132 and an output stage 134. In some embodiments, the amplification stages 132, 134 can include, for example, HBT or CMOS amplification transistors.

In the example of FIG. 6, the collector of the output stage 134 is shown to be provided with a supply voltage VCC from a boost DC/DC converter through an envelope tracking (ET) modulator 150 through a choke inductance 124. The ET modulator 150 is depicted as being part of an ET modulation system 112. The supply voltage VCC provided by such an ET modulator is typically determined in a dynamic manner, and can have a value in a range of, for example, about 1V to 3V. The ET modulator 150 is shown to generate such a dynamic VCC voltage based on a battery voltage Vbatt.

When the amplification path 130 is operated in the foregoing manner, its impedance Z is relatively low (e.g., about 3 to 5Ω); and thus, impedance transformation typically needs to occur to match with impedance associated with a downstream component. In the example of FIG. 6, a band select switch 138 (depicted as being part of a band select switch system 118) that receives the output of the amplification path 130 is typically configured as a 50Ω load. Accordingly, and assuming that the impedance (Z) presented by the amplification path 130 is about 4Ω, an impedance transformation of about 13:1 (50:4) needs to be implemented. In the example of FIG. 6, such an impedance transformation is shown to be implemented by an output matching network (OMN) 136 which is depicted as being part of a load transform system 116.

In the example of FIG. 6, the band select switch 138 is depicted as having a single input from the output of the amplification path 130 (through the OMN 136), and three outputs corresponding to three example frequency bands. Three duplexers 142a-142c are shown to be provided for such three frequency bands.

Each of the three duplexers 142a-142c is shown to include TX and RX filters (e.g., bandpass filters). Each TX filter is shown to be coupled to the band select switch 138 to receive the corresponding amplified and switch-routed RF signal for transmission. Such an RF signal is shown to be filtered and routed to an antenna port (ANT) (144a, 144b or 144c). Each RX filter is shown to receive an RX signal from the corresponding antenna port (ANT) (144a, 144b or 144c). Such an RX signal is shown to be filtered and routed to an RX component (e.g., an LNA) for further processing.

It is typically desirable to provide impedance matching between a given duplexer and a component that is upstream (in the TX case) or downstream (in the RX case). In the example of FIG. 6, the band select switch 138 is such an upstream component for the TX filter of the duplexer. Accordingly, matching circuits 140a-140c (depicted as being parts of, for example, a PI network 120) are shown to be implemented between the outputs of the band select switch 138 and the respective duplexers 142a-142c. In some embodiments, each of such matching circuits 140a-140c can be implemented as, for example, a pi-matching circuit.

Table 1 lists example values of insertion loss and efficiency for the various components of the band select switch power amplification system 110 of FIG. 6. It will be understood that the various values listed are approximate values.

TABLE 1

| Component | Insertion loss | Efficiency |
|---|---|---|
| ET Mod (112) | N/A | 83% |
| Power Amp. | N/A | 70% to 75% |
| Assy. (114) | | (PAE) |
| Load Transform | 0.5 dB to 0.7 dB | 85% to 89% |
| (116) | | |
| Band Select | 0.5 dB to 1 dB | 79% to 89% |
| Switch (118) | | |
| PI (120) | 0.3 dB | 93% |
| Duplex (122) | 2.0 dB | 63% |

From Table 1, one can see that the band select switch power amplification system 110 of FIG. 6 includes a significant number of loss contributors. Even if each component of the system 110 is assumed to operate at its upper limit of efficiency, the total efficiency of the band select switch power amplification system 110 is approximately 29% (0.83×0.75×0.89×0.89×0.93×0.63).

In the example of FIG. 7, the parallel cascode output stages power amplification system 100 is depicted as being configured to provide amplification for the same three frequency bands as in the example band select switch power amplification system 110 of FIG. 6. In a power amplifier assembly 104, three separate amplification paths can be implemented, such that each amplification path provides amplification for its respective frequency band. The three separate amplification paths can be implemented using a parallelly connected cascode output stages that share a common cascode input stage, which expands on the two parallelly connected cascode output stages shown in FIG. 4A-4C. For example, the first amplification path is shown to include a first cascode output stage 168a which receives an RF signal from an input node 162 through a DC-block capacitance 164 and a cascode input stage 163. The amplified RF signal from the first cascode output stage 168a is shown to be routed to a downstream component through a capacitance 170a. Similarly, the second amplification path is shown to include a second cascode output stage 168b which receives an RF signal from an input node 162 through a DC-block capacitance 164 and the cascode input stage 163; and the amplified RF signal from the second cascode output stage 168b is shown to be routed to a downstream component through a capacitance 170b. Similarly, the third amplification path is shown to include a third cascode output stage 168c which receives an RF signal from an input node 162 through a DC-block capacitance 164 and the cascode input stage 163; and the amplified RF signal from the third cascode output stage 168c is shown to be routed to a downstream component through a capacitance 170c. Each of the three amplification paths are activated/deactivated based on selective application of respective forward-biasing voltages V_{CAS1}, V_{CAS2}, and V_{CAS3}. As described in relation to FIGS. 4B-4C and FIG. 5, the selective application of voltages can apply the forward-biasing voltages V_{CAS1}, V_{CAS2}, and V_{CAS3} in alternating phases.

In some embodiments, some or all of the cascode input stage 163 and cascode output stages 168a-168c can include, for example, HBT PAs. It will be understood that one or more features of the present disclosure can also be implemented with other types of PAs. For example, PAs that can be operated to yield impedances that match or are close to downstream components (e.g., by HV operation and/or through other operating parameter(s)) can be utilized to yield one or more of the benefits as described herein.

In the example of FIG. 7, each cascode output stage (168a, 168b or 168c) PA is shown to be provided with a supply voltage VCC from a boost DC/DC converter 160 through a choke inductance (166a, 166b, or 166c). The boost DC/DC converter 160 is depicted as being part of an HV system 102. The boost DC/DC converter 160 can be configured to supply such a range of VCC voltage values (e.g., about 1V to 11V), including HV ranges or values as described herein. The boost DC/DC converter 160 is shown to generate such a high VCC voltage based on a battery voltage Vbatt.

When the PAs 168a-168c are operated in the foregoing manner with high VCC voltage (e.g., at about 11V), impedance Z of each PA is relatively high (e.g., about 40Ω to 50Ω); and thus, impedance transformation is not necessary to match with impedance associated with a downstream component. In the example of FIG. 7, each of the duplexers 174a-174c (depicted as being parts of a duplex assembly 108) that receives the output of the corresponding PA (168a, 168b, or 168c) is typically configured as a 50Ω load. Accordingly, and assuming that the impedance (Z) presented by the PA (168a, 168b, or 168c) is about 50Ω, an impedance transformation (such as the load transform system 116 in FIG. 6) is not needed. In some embodiments, output signals 176a-176c from the duplexers 174a-174c can be provided to an antenna switch module, such as the antenna switch module 622 of FIG. 4A.

It is typically desirable to provide impedance matching between a given duplexer and a component that is upstream (in the TX case) or downstream (in the RX case). In the example of FIG. 7, each cascode output stage (168a, 168b or 168c) PA is such an upstream component for the TX filter of the duplexer (174a, 174b or 174c). Accordingly, matching circuits 172a-172c (depicted as being parts of, for example, a PI network 106) can be implemented between the respective outputs of the PAs 168a-168c and the respective duplexers 174a-174c. In some embodiments, each of such matching circuits 172a-172c can be implemented as, for example, a pi-matching circuit.

In the example of FIG. 7, the HV operation of the cascode output stage 168a-168c PAs can result in each of the PAs presenting an impedance Z that is similar to the impedance of the corresponding duplexer. Since impedance transformation is not needed in such a configuration, there is no need for an impedance transformer (116 in FIG. 6).

It is also noted that operation of the PAs 168a-168c at the higher impedance can result in much lower current levels within the PAs 168a-168c. Such lower current levels can allow the PAs 168a-168c to be implemented in significantly reduced die size(s).

In some embodiments, either or both of the foregoing features (elimination of impedance transformer and reduced PA die size) can provide additional flexibility in power amplification architecture design. For example, space and/or cost savings provided by the foregoing can allow implementation of a relatively small cascode output stage (168a, 168b or 168c in FIG. 7) PA for each frequency band, thereby removing the need for a band select switch system (e.g., 118 in FIG. 6). Accordingly, size, cost and/or complexity associated with the parallel cascode output stages power amplification system 100 of FIG. 7 can be maintained or reduced when compared to the band select switch power amplification system 110 of FIG. 6, while significantly reducing the overall loss of the power amplification system 100.

Table 2 lists example values of insertion loss and efficiency for the various components of the parallel cascode output stages power amplification system 100 of FIG. 7. It will be understood that the various values listed are approximate values.

TABLE 2

| Component | Insertion loss | Efficiency |
|---|---|---|
| HV (102) | N/A | 93% |
| Power Amp. | N/A | 80% to 82% |
| Assy. (104) | | (PAE) |
| PI (106) | 0.3 dB | 93% |
| Duplex (108) | 2.0 dB | 63% |

From Table 2, one can see that the parallel cascode output stages power amplification system 100 of FIG. 7 includes a number of loss contributors. However, when compared to the band select switch power amplification system 110 of FIG. 6 and Table 1, two significant loss contributors (Load Transform (116) and band select switch (118)) are absent in the parallel cascode output stages power amplification system 100 of FIG. 7. Elimination of such loss contributors is shown to remove about 1 dB in the transmit path in the example of FIG. 7 and Table 2.

Also referring to Table 2, if each component of the system 100 is assumed to operate at its upper limit of efficiency (as in the example of Table 1), the total efficiency of the parallel cascode output stages power amplification system 100 is approximately 45% (0.93×0.82×0.93×0.63). Even if each component is assumed to operate at its lower limit of efficiency, the total efficiency of the parallel cascode output stages power amplification system 100 is approximately 44% (0.93×0.80×0.93×0.63). One can see that in either case, the total efficiency of the parallel cascode output stages power amplification system 100 of FIG. 7 is significantly higher than the total efficiency (approximately 36%) of the band select switch power amplification system 110 of FIG. 6.

Referring to FIGS. 6 and 7, a number of features can be noted. It is noted that use of the DC/DC boost converter (160 in FIG. 7) can allow elimination of one or more other power converters that may be utilized in a PA system. For example, when operated to yield an HV supply voltage (e.g., 11 VDC), 1 Watt (11V)²/(2×50Ω)) of RF power can be produced with no harmonic terminations.

It is further noted that a PA driven as a 50Ω load (e.g., FIG. 7) results in a significantly lower loss per Ohm than a PA driven as a 3Ω load (e.g., FIG. 6). For example, an equivalent series resistance (ESR) of 0.1Ω has an insertion loss of about 0.14 dB when the PA is driven at 3Ω, while for the PA driven at 50Ω, an ESR of 0.1Ω has an insertion loss of about 0.008 dB. Accordingly, the 3Ω PA can have a total insertion loss of about 4.2 dB (0.14 dB×30), while the 50Ω PA can have a total insertion loss of about 4.0 dB (0.008 dB×500), which is still less than the total insertion loss for the 3Ω PA.

It is further noted that the 50Ω PA can have a significantly higher gain than the 3Ω PA. For example, gain can be approximated as G_{M}×R_{LL}; if G_{M} is similar for both cases, then the higher value of 50Ω yields a higher gain.

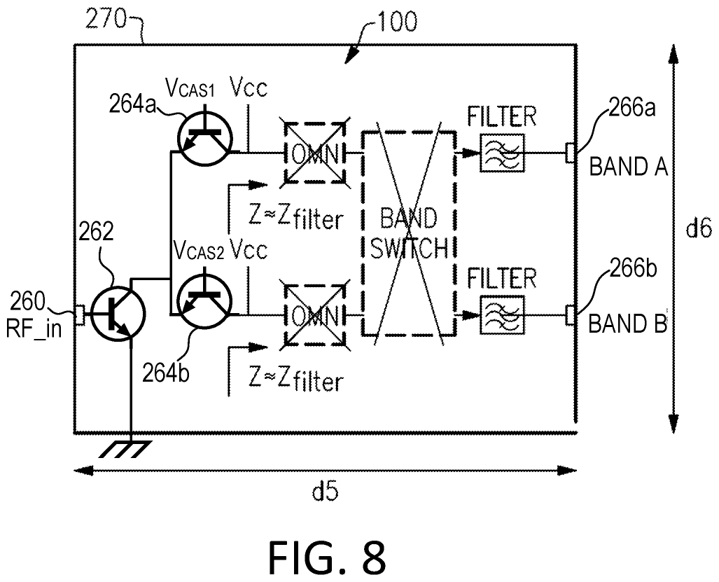

FIG. 8 show examples of advantageous benefits that can be obtained in parallel cascode output stages power amplification systems having one or more features as described herein. As described herein, FIG. 8 shows that in some embodiments, a power amplification system 100 can include a cascode input stage PA configured to receive an RF signal (RF_in) at an input node 260. A collector of the cascode input stage 262 PA can be parallelly connected to a plurality of cascode output stage 264a-264b PAs at their respective emitters. The respective collectors of the plurality of cascode output stage PAs can be provided with a supply voltage of Vcc, and such a supply voltage can include a high-voltage (HV) value as described herein. Each cascode output stage PA can provide an amplified RF signal as RF_out, which is routed to a filter that is configured to condition the amplified RF signal and yield a filtered signal at corresponding output nodes 266a-266b. The cascode output stage 264a-264b PAs can be operated (e.g., in an HV mode) to be driven at approximately a characteristic load impedance of the filter. Such a characteristic load impedance of the filter can be, for example, approximately 50 Ohms.

The power amplification system 100 can be configured to process RF signals for a plurality of bands. Such bands can be, for example, Band A and Band B. It will be understood that other numbers of bands can be implemented for the power amplification system 100. each band is shown to have associated with it a separate amplification path. In each amplification path, its PA, supply voltage Vcc, and filter can be configured and operated similar to the example of FIG. 7.

Each of some or all of the plurality of amplification path can be substantially free of an output matching network (OMN) (also referred to herein as an impedance transformation circuit). Accordingly, a device 270 (such as a PA die or a PA module) having some or all of the power amplification system 100 can have reduced dimensions (e.g., d5×d6). Further, other advantageous features such as reduced loss and improved efficiency can also be realized with the elimination of the band selection switch and some or all of the OMNs.

The device 270 on which its respective power amplification system 100 is implemented can be, for example, a power amplifier die having a semiconductor substrate. Cascode output stages of the plurality of PAs can be implemented in parallel as shown on the semiconductor substrate, and each cascode output stage 264a-264b PA can be configured to drive an individual narrow frequency band signal path. Thus, each PA can be sized smaller than a wide band PA capable of driving more than one of the frequency bands associated with the plurality of PAs. As described herein, use of such miniaturized single-band PAs can yield a number of desirable features.

For example, a less complex supply configuration, reduced loss, and improved efficiency can be realized. In another example, the foregoing PA, a die having the foregoing power amplification system 100, and/or a module having the foregoing power amplification system 100 can be implemented in as a reduced-sized device. For instance, a band select switch is typically implemented in a separate technology from the power amplifier technology and the removal of the band select switch can eliminate a separate SOI die. In some embodiments, such reduced-sized device can be realized at least in part due to elimination of some or all of the PA's output matching networks (OMNs) in a power amplification system.

There are additional advantages. The higher Vcc (e.g., 11V) can provide more headroom for the cascode output stages 264a-264b to enable the cascade topology with less knee voltage degradation. The native 50Ω output impedance without OMN helps the device 270 avoid the penalty of SMT and impedance match networks required for each separate output. Further, additional choke inductors and access to the separate outputs can further enable optimization of the loadline per amplification path for more optimal efficiency and linearity and filter contour matching as desired.

With the proposed improvements, it may be possible to provide reduced out-of-band gain with the dedicated outputs managed for specific frequency ranges and providing separate choke/load inductance. Push-pull embodiments and Doherty embodiments may leverage the proposed parallelly connected cascode output stages to eliminate band select switching for the Doherty Tx topologies as well.

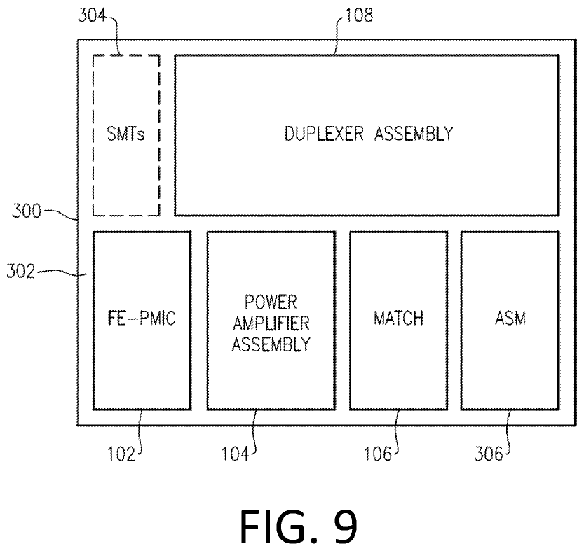

FIG. 9 shows that in some embodiments, some or all of a parallel cascode output stages power amplification system having one or more features as described herein can be implemented in a module. Such a module can be, for example, a front-end module (FEM). In the example of FIG. 9, a module 300 can include a packaging substrate 302, and a number of components can be mounted on such a packaging substrate. For example, an FE-PMIC component 102, a power amplifier assembly 104, a match component 106, and a duplexer assembly 108 can be mounted and/or implemented on and/or within the packaging substrate 302. Other components such as a number of SMT devices 304 and an antenna switch module (ASM) 306 can also be mounted on the packaging substrate 302. Although all of the various components are depicted as being laid out on the packaging substrate 302, it will be understood that some component(s) can be implemented over or under other component(s).

In some implementations, a power amplification system having one or more features as described herein can be included in an RF device such as a wireless device. Such a power amplification system can be implemented in the wireless device as one or more circuits, as one or more die, as one or more packaged modules, or in any combination thereof. In some embodiments, such a wireless device can include, for example, a cellular phone, a smart phone, a hand-held wireless device with or without phone functionality, a wireless tablet, etc.

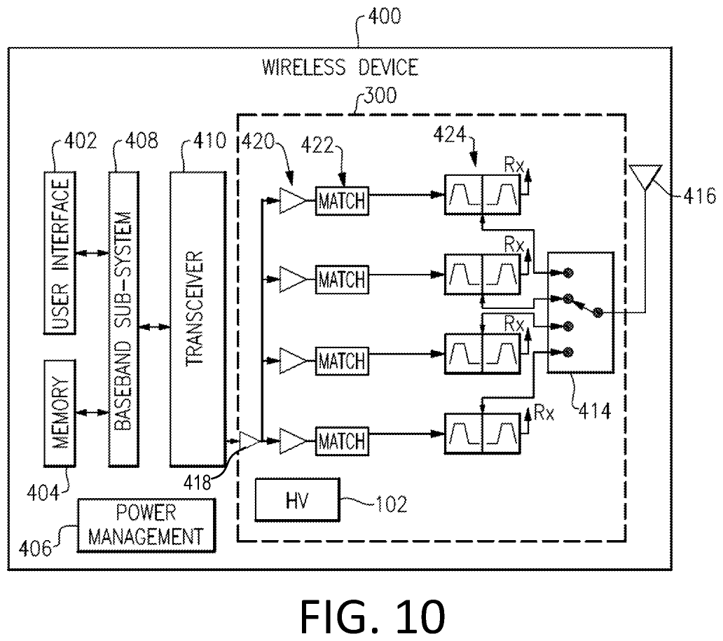

FIG. 10 depicts an example wireless device 400 having one or more advantageous features described herein. In the context of a module having one or more features as described herein, such a module can be generally depicted by a dashed box 300, and can be implemented as, for example, a front-end module (FEM).

Referring to FIG. 10, cascode output stage power amplifiers (PAs) 420 can receive their respective signals from a cascode input stage PA 418, which in turn receives an RF signal from a transceiver 410. The transceiver 410 can be configured and operated to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 can also be in communication with a power management component 406 that is configured to manage power for the operation of the wireless device 400. Such power management can also control operations of the baseband sub-system 408 and the module 300.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 420 are shown to be matched (via respective match circuits 422) and routed to their respective duplexers 424. In some embodiments, the match circuit 422 can be similar to the example matching circuits 172a-172c described herein in reference to FIG. 7. As also described herein in reference to FIG. 7, the outputs of the PAs 420 can be routed to their respective duplexers 424 without impedance transformation (e.g., with load transformation 116 in FIG. 6) when the PAs 420 are operated in an HV mode with HV supply. Such amplified and filtered signals can be routed to an antenna 416 through an antenna switch 414 for transmission. In some embodiments, the duplexers 424 can allow transmit and receive operations to be performed simultaneously using a common antenna (e.g., 416). In FIG. 10, received signals are shown to be routed through the duplexers 424 to “Rx” paths that can include, for example, one or more low-noise amplifiers (LNAs).

In the example of FIG. 10, the foregoing HV supply for the PAs 420 can be provided by an HV component 102. Such an HV component can include, for example, a boost DC/DC converter as described herein.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

As described herein, one or more features of the present disclosure can provide a number of advantages when implemented in systems such as those involving the wireless device of FIG. 10. For example, significant current drain reduction can be achieved through an elimination or reduction of output loss. In another example, lower bill of materials count can be realized for the power amplification system and/or the wireless device. In yet another example, independent optimization or desired configuration of each supported frequency band can be achieved due to, for example, separate PAs for their respective frequency bands. In yet another example, optimization or desired configuration of maximum or increased output power can be achieved through, for example, a boost supply voltage system. In yet another example, a number of different battery technologies can be utilized, since maximum or increased power is not necessarily limited by battery voltage.

In the description herein, references are made to various forms of impedance. For example, a PA is sometimes referred to as driving a load impedance of a downstream component such as a filter. In another example, a PA is sometimes referred to as having an impedance value. For the purpose of description, it will be understood that such impedance-related references to a PA may be used interchangeably. Further, an impedance of a PA can include its output impedance as seen on the output side of the PA. Accordingly, such a PA being configured to drive a load impedance of a downstream component can include the PA having an output impedance that is approximately same as the load impedance of the downstream component.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplification system comprising:
a cascode power amplifier (PA) configured to receive and amplify a radio-frequency (RF) signal, the cascode PA including:
a shared common cascode input stage; and
a plurality of cascode output stages parallelly connected to the shared common cascode input stage, each cascode output stage associated with a frequency band.

2. The power amplification system of claim 1 wherein the plurality of cascode output stages include a first cascode output stage and a second cascode output stage, the first cascode output stage associated with a first frequency band and a second cascode output stage associated with a second frequency band.

3. The power amplification system of claim 2 wherein the first cascode output stage receives an amount of voltage that activates the first cascode output stage to provide a first amplification path for the RF signal while the second cascode output stage does not receive the amount of voltage and does not provide a second amplification path.

4. The power amplification system of claim 3 wherein the first cascode output stage stops receiving the amount of voltage and stops providing the first amplification path for the RF signal while the second cascode output stage receives the amount of voltage to provide the second amplification path for the RF signal.

5. The power amplification system of claim 3 wherein provision of the first amplification path and the second amplification path alternates in a non-overlapping manner.

6. The power amplification system of claim 2 wherein the cascode input stage includes a first bipolar junction transistor (BJT), the first cascode output stage includes a second BJT, the second cascode output stage includes a third BJT, and a voltage greater than a forward-biasing voltage is applied to the second BJT while not applied to the third BJT.

7. The power amplification system of claim 2 wherein the cascode input stage includes a BJT, the first cascode output stage includes a first field-effect-transistor (FET), the second cascode output stage includes a second FET, and a voltage greater than a threshold voltage is applied to the first FET while not applied to the second FET.

8. The power amplification system of claim 1 further comprising a voltage supply system configured to provide a voltage greater than or equal to 11V to the plurality of cascode output stages, wherein the voltage supply system includes a boost DC/DC converter configured to generate the voltage based on a battery voltage.

9. The power amplification system of claim 8 wherein the voltage is provided to collectors of the plurality of cascode output stages.

10. The power amplification system of claim 1 wherein the plurality of cascode output stages have impedances of approximately 50 Ohms.

11. The power amplification system of claim 2 further comprising a transmit (Tx) filter coupled to the first cascode output stage and configured to condition a signal output by the first cascode output stage, the Tx filter configured to operate in the first frequency band.

12. The power amplification system of claim 11 wherein the Tx filter is coupled to the first cascode output stage by an amplification path that is free of an impedance transformation circuit.

13. The power amplification system of claim 12 wherein the Tx filter is coupled to the first cascode output stage by an amplification path that is free of a band select switch.

14. A wireless device comprising:
a transceiver configured to generate a radio-frequency (RF) signal;
a front-end module (FEM) in communication with the transceiver, the FEM including a packaging substrate configured to receive a plurality of components, the FEM further including a power amplification system implemented on the packaging substrate, the power amplification system including a cascode power amplifier (PA), the cascode PA including a shared common cascode input stage and a shared common cascode input stage and a plurality of cascode output stages parallelly connected to the shared common cascode input stage, each cascode output stage associated with a frequency band, the cascode PA configured to receive and amplify a radio-frequency (RF) signal; and
an antenna in communication with the FEM, the antenna configured to transmit the amplified RF signal.

15. The wireless device of claim 14 wherein the plurality of cascode output stages include a first cascode output stage and a second cascode output stage, the first cascode output stage associated with a first frequency band and a second cascode output stage associated with a second frequency band.

16. The wireless device of claim 15 wherein the first cascode output stage receives an amount of voltage that activates the first cascode output stage to provide a first amplification path for the RF signal while the second cascode output stage does not receive the amount of voltage and does not provide the second amplification path.

17. The wireless device of claim 16 wherein the first cascode output stage stops receiving the amount of voltage and stops providing the first amplification path for the RF signal while the second cascode output stage receives the amount of voltage to provide a second amplification path for the RF signal.

18. The wireless device of claim 17 wherein provision of the first amplification path and the second amplification path alternates in a non-overlapping manner.

19. The wireless device of claim 16 wherein the first amplification path is free of a band select switch.

20. A method for processing a radio-frequency (RF) signal, the method comprising:
providing a cascode power amplifier (PA) including a shared cascode input stage and a first cascode output stage and a second cascode output stage parallelly connected to the shared cascode input stage, the first cascode output stage associated with a first frequency band and the second cascode output stage associated with a second frequency band;
applying an amount of voltage that activates the first cascode output stage to provide a first amplification path while not applying the amount of voltage to the second output stage to block a second amplification path;
amplifying the RF signal with the cascode PA with the shared cascode input stage and the first cascode output stage through the first amplification path;
routing the amplified RF signal to a downstream filter associated with the first frequency band.
